(19) United States
(12) Patent Application Publication
(10) Pub. No.: US 2025/0215251 A1
(43) Pub. Date: Jul. 3, 2025

(54) QUANTUM DOT INK COMPOSITION AND DISPLAY DEVICE INCLUDING THE SAME

(71) Applicant: Samsung Display Co., LTD., Yongin-si (KR)

(72) Inventors: Sang Hee YU, Yongin-si (KR); Gyu Bong KIM, Yongin-si (KR); Yun Hyuk KO, Yongin-si (KR); Se Hun KIM, Yongin-si (KR); Hoi Lim KIM, Yongin-si (KR); Gye Hyun PARK, Yongin-si (KR); Dong Woo SHIN, Yongin-si (KR); Soo Ho LEE, Yongin-si (KR); Jae Kook HA, Yongin-si (KR)

(21) Appl. No.: 18/773,271

(22) Filed: Jul. 15, 2024

(30) Foreign Application Priority Data
Jan. 2, 2024 (KR) 10-2024-0000265

(51) Int. Cl. C09D 11/50; B82Y 20/00; C09D 11/037; C09D 11/101; H01L 27/15; H01L 33/50

(52) U.S. Cl. CPC C09D 11/50; C09D 11/037; C09D 11/101; H10H 20/8512; H10H 29/142; B82Y 20/00

(57) ABSTRACT

A quantum dot ink composition includes: a quantum dot, a solvent, and a phosphine compound.

### CROSS-REFERENCE TO RELATED APPLICATION

The present application claims priority to and the benefit of Korean Patent Application No. 10-2024-0000265, filed on Jan. 2, 2024, in the Korean Intellectual Property Office, the entire content of which is incorporated herein by reference.

### BACKGROUND

### 1. Field

The present disclosure relates to a quantum dot ink composition and a display device including the quantum dot ink composition.

### 2. Description of Related Art

As information technology develops, importance of a display device, which is a connection medium between a user and information (the digital information), is emerging. Accordingly, the usage of a display device, such as a liquid crystal display device and/or an organic light emitting display device, is increasing.

A quantum dot is a nanocrystal of a semiconductor material that exhibits a quantum confinement effect. When the quantum dot receives light from an excitation source and reaches an excited energy state, the quantum dot independently emits energy according to a corresponding energy band gap. Because the quantum dot may exhibit a characteristic of relatively excellent (e.g., high or suitable) color purity, relatively high emission efficiency, and/or the like, the quantum dot may be applied to various suitable elements (the display elements) or devices.

### SUMMARY

Aspects according to embodiments of the present disclosure are directed toward a quantum dot ink composition capable of improving emission efficiency of a quantum dot, and a display device including the quantum dot ink composition.

Additional aspects will be set forth in part in the description which follows and, in part, will be apparent from the description, or may be learned by practice of the presented embodiments of the disclosure.

According to one or more embodiments of the present disclosure, a quantum dot ink composition may include a quantum dot, a solvent, and a phosphine compound.

The phosphine compound may be 20% or less by weight based on a total weight of the quantum dot ink composition.

The phosphine compound may include one kind of phosphine compound or two or more kinds of phosphine compounds (e.g., two or more phosphine compounds having different number of phosphine atoms and/or different alkyl groups).

The phosphine compound may be a compound represented by PR₃, where R is CₙH₂ₙ₊₁ and n is an integer selected from 2 to 8.

The phosphine compound may include a first compound represented by P(R₁)₃, where R₁ is CₚH₂ₚ₊₁ and p is an integer selected from an integer selected from 2 to 8, and a second compound represented by P(R₂)₃, where R₂ is C_{q}H_{2q+1} and q is an integer selected from 2 to 8 excluding p (e.g., p and q are different).

Each of the first compound and the second compound may be 10% or less by weight based on a total weight of the quantum dot ink composition.

The quantum dot ink composition may further include a monomer, a dispersant, a scattering agent, and an initiator.

The phosphine compound may react with oxygen to suppress or reduce photocorrosion of the quantum dot.

The quantum dot may include a Group II-VI semiconductor compound, a Group III-V semiconductor compound, a Group III-VI semiconductor compound, a Group I-III-VI semiconductor compound, a Group IV-VI semiconductor compound, a Group IV element or compound, or any combination thereof.

According to one or more embodiments of the present disclosure, a display device may include a substrate, a pixel circuit layer on the substrate, a light emitting element layer on the pixel circuit layer, and a color conversion layer including a quantum dot ink composition, and the quantum dot ink composition may include a quantum dot, a solvent, and a phosphine compound.

The color conversion layer may be adjacent to the light emitting element layer.

The phosphine compound may be 20% (wt %) or less by weight based on a total weight (of 100% or 100 wt %) of the quantum dot ink composition.

The phosphine compound may include one kind of phosphine compound or two or more kinds of phosphine compounds (e.g., two or more phosphine compounds having different number of phosphine atoms and/or different alkyl groups).

The phosphine compound may be a compound represented by PR₃, where R is CₙH₂ₙ₊₁ and n is an integer selected from 2 to 8.

The phosphine compound may include a first compound represented by P(R₁)₃, where R₁ is CₚH₂ₚ₊₁ and p is an integer selected from 2 to 8 and a second compound represented by P(R₂)₃, where R₂ is C_{q}H_{2q+1} and q is an integer selected from 2 to 8 excluding p (e.g., p and q are different).

Each of the first compound and the second compound may be 10% (wt %) or less by weight based on a total weight (of 100% or 100 wt %) of the quantum dot ink composition.

The quantum dot ink composition may further include a monomer, a dispersant, a scattering agent, and an initiator.

The phosphine compound may react with oxygen to suppress or reduce photocorrosion of the quantum dot.

### BRIEF DESCRIPTION OF THE DRAWINGS

The above and other aspects and features of the present disclosure will become more apparent by describing, in further detail, embodiments thereof with reference to the accompanying drawings, in which:

FIG. 1 is a plan view schematically illustrating a display device in accordance with one or more embodiments.

FIG. 2 is a circuit diagram schematically illustrating a sub-pixel in accordance with one or more embodiments.

FIG. 3 is a perspective view schematically illustrating a light emitting element in accordance with one or more embodiments.

FIG. 4 is a cross-sectional view schematically illustrating a light emitting element in accordance with one or more embodiments.

FIG. 5 is a plan view schematically illustrating a sub-pixel in accordance with one or more embodiments.

FIG. 6 is a cross-sectional view taken along the line A-A′ of FIG. 5.

FIG. 7 is a cross-sectional view schematically illustrating a sub-pixel in accordance with one or more embodiments.

FIG. 8 is a cross-sectional view schematically illustrating a sub-pixel in accordance with one or more embodiments.

FIG. 9 is a diagram schematically illustrating a deterioration phenomenon of a quantum dot.

FIGS. 10 and 11 are diagrams schematically illustrating a function of an additive.

### DETAILED DESCRIPTION

Hereinafter, embodiments according to the disclosure will be described in more detail with reference to the accompanying drawings. It should be noted that in the following description, only portions necessary for understanding an operation according to the disclosure are described, and descriptions of other portions may be omitted in order not to obscure the subject matter of the disclosure. In addition, the disclosure may be embodied in other suitable forms without being limited to the embodiments described herein. However, the embodiments described herein are provided to describe the technical spirit of the disclosure in sufficient detail to allow those skilled in the art to which the disclosure belongs to easily implement the present disclosure.

Throughout the specification, when a portion is described as “connected” to another portion, it includes not only a case where the portions are “directly connected” but also a case where the portions are “indirectly connected” with other element(s) interposed therebetween. Terms as used herein are for describing specific embodiments and are not intended to limit the scope of the disclosure. Throughout the specification, it will be further understood that the terms “includes” and/or “comprises” as used herein may specify the presence of stated features or elements, but do not preclude the presence or addition of one or more other features or elements. “At least any one of X, Y, and Z” and “at least any one selected from among a group including (e.g., consisting of) X, Y, and Z” may be interpreted as one X, one Y, one Z, or any suitable combination of two or more of X, Y, and Z (for example, XYZ, XYY, YZ, or ZZ). Here, “and/or” includes all combinations of one or more of corresponding configurations.

Here, terms such as “first” and “second” may be used to describe one or more suitable components, but these components are not limited to these terms. These terms are used to distinguish one component from another component. Therefore, a first component may refer to a second component within a range without departing from the scope disclosed herein.

Spatially relative terms such as “under”, “on”, and/or the like may be used for descriptive purposes, thereby describing a relationship between one element or feature and another element(s) or feature(s) as shown in the drawings. Spatially relative terms are intended to include other directions in use, in operation, and/or in manufacturing, in addition to the direction depicted in the drawings. For example, when a device shown in the drawing is turned upside down, elements depicted as being positioned “under” other elements or features are positioned in a direction “on” the other elements or features. Therefore, in one or more embodiments, the term “under” may include both directions of on and under. In addition, the device may face in other directions (for example, rotated 90 degrees or in other directions) and thus the spatially relative terms used herein are interpreted according thereto.

Various embodiments are described with reference to the drawings schematically illustrating example embodiments. Accordingly, it will be expected that shapes may vary, for example, according to tolerances and/or manufacturing techniques. Therefore, one or more embodiments disclosed herein cannot be construed as being limited to the specific shapes shown, and should be interpreted as including, for example, suitable changes in shapes that occur as a result of manufacturing. As described above, the shapes shown in the drawings may not be the actual shapes of areas of a device, and the present embodiments are not limited thereto.

Hereinafter, embodiments of the present disclosure will be described in more detail with reference to the accompanying drawings.

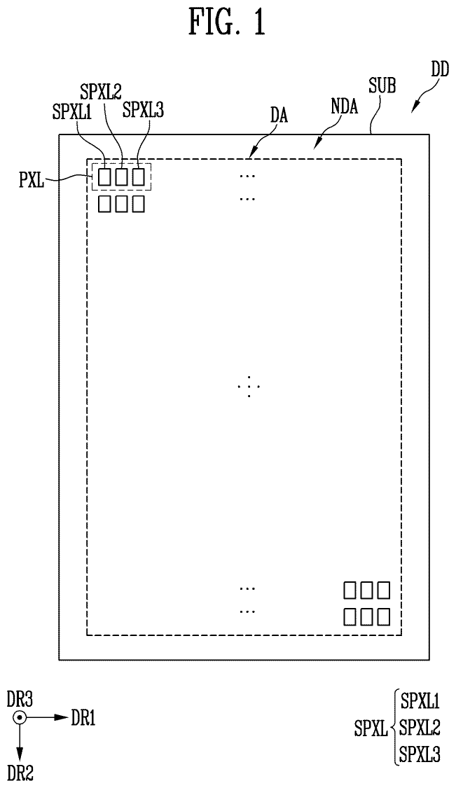

FIG. 1 is a plan view schematically illustrating a display device in accordance with one or more embodiments.

Referring to FIG. 1, the display device DD may include a substrate SUB and pixels PXL arranged on the substrate SUB. Each of the pixels PXL may include a first sub-pixel SPXL1, a second sub-pixel SPXL2, and/or a third sub-pixel SPXL3. Hereinafter, when at least one sub-pixel among the first sub-pixel SPXL1, the second sub-pixel SPXL2, and the third sub-pixel SPXL3 is arbitrarily referred to or when two or more types (kinds) of sub-pixels are comprehensively (e.g., collectively) referred to, the at least one sub-pixel or the two or more types (kinds) of sub-pixels are referred to as a “sub-pixel SPXL” or “sub-pixels SPXL”.

The substrate SUB may configure (e.g., provide) a base member of the display device DD and may be a rigid or flexible substrate or film. For example, the substrate SUB may be formed of a rigid substrate formed of glass or tempered glass, or a flexible substrate (or thin film) of a plastic or metal material, and a material and/or a physical property of the substrate SUB are/is not particularly limited.

The substrate SUB may include a display area DA for displaying an image and a non-display area NDA excluding the display area DA. The pixels PXL may be arranged in the display area DA. Various lines, pads, and/or built-in circuits connected to the pixels PXL of the display area DA may be arranged in the non-display area NDA. The pixels PXL may be arranged regularly according to a stripe or pentile (PENTILE®) arrangement structure. PENTILE® is a trademark of Samsung Display Co., Ltd. However, an arrangement structure of the pixels PXL is not limited thereto, and the pixels PXL may be arranged in the display area DA in one or more suitable structures and/or methods.

The pixels PXL may include two or more types (kinds) of sub-pixels SPXL respectively emitting light of different colors. For example, in the display area DA, first sub-pixels SPXL1 emitting light of a first color, second sub-pixels SPXL2 emitting light of a second color, and third sub-pixels SPXL3 emitting light of a third color may be arranged. At least one first to third sub-pixels SPXL1, SPXL2, and SPXL3 arranged adjacent to each other may form one pixel PXL capable of emitting light of one or more suitable colors. For example, the first sub-pixel SPXL1 may be a red pixel for emitting red light, the second sub-pixel SPXL2 may be a green pixel for emitting green light, and the third sub-pixel SPXL3 may be a blue pixel for emitting blue light, but the disclosure is not limited thereto.

In one or more embodiments, the first sub-pixel SPXL1, the second sub-pixel SPXL2, and the third sub-pixel SPXL3 may have light emitting elements emitting light of the same color, may include color conversion layers and/or color filters of different colors arranged on each light emitting element, and thus may be to emit light of the first color, the second color, and the third color, respectively. In one or more embodiments, the first sub-pixel SPXL1, the second sub-pixel SPXL2, and the third sub-pixel SPXL3 may include a first color light emitting element, a second color light emitting element, and a third color light emitting element, and thus may emit light of the first color, the second color, and the third color, respectively. However, a color, a type or kind, the number, and/or the like of the sub-pixels SPXL configuring (e.g., forming) each of the pixels PXL are/is not particularly limited.

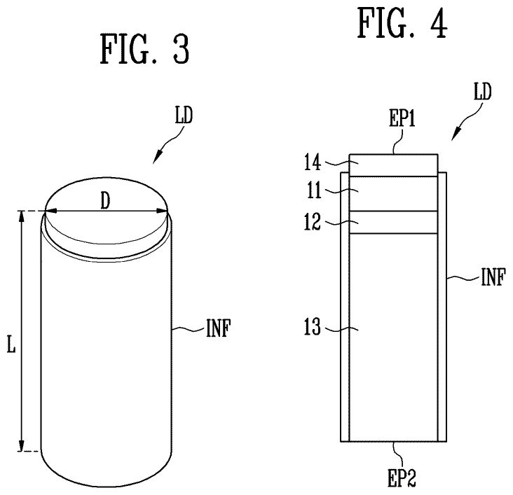

The sub-pixel SPXL may include at least one light source driven by a set or predetermined control signal (for example, a scan signal and a data signal) and/or a set or predetermined power (for example, first driving power and second driving power). The light source may include at least one light emitting element LD shown in FIGS. 3 and 4, for example, an ultra-small column shaped light emitting element LD having a size as small as in the nanometer scale to micrometer scale. However, the disclosure is not necessarily limited thereto, and one or more suitable types (kinds) of light emitting elements LD may be utilized as the light source of the sub-pixel SPXL.

In one or more embodiments, each sub-pixel SPXL may be configured (e.g., formed) as an active pixel. However, a type or kind, a structure, and/or a driving method of the sub-pixels SPXL that may be applied to the display device DD are/is not particularly limited. For example, each sub-pixel SPXL may be configured (e.g., formed) as a pixel of a passive or active light emitting display device with one or more suitable structures and/or driving methods.

For convenience of description, a structure of the display device DD is schematically shown in FIG. 1 based on the display area DA. However, according to one or more embodiments, at least one driving circuit unit (for example, at least one of a scan driver or a data driver), lines, and/or pads which are not shown may be included in the display device DD.

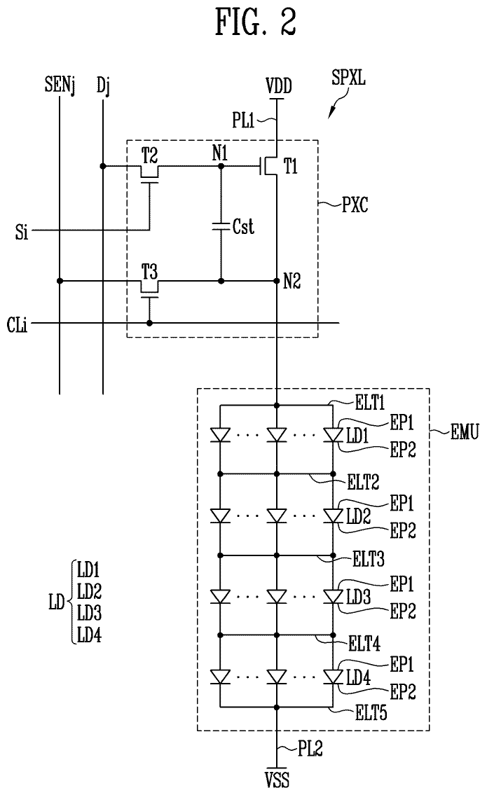

FIG. 2 is a circuit diagram schematically illustrating a sub-pixel in accordance with one or more embodiments.

FIG. 2 shows an electrical connection relationship of components included in each of the first to third sub-pixels SPXL1, SPXL2, and SPXL3 shown in FIG. 1, and the components included in each of the first to third sub-pixels SPXL1, SPXL2, and SPXL3 are not necessarily limited thereto. In addition, in FIG. 2, not only the components included in each of the first to third sub-pixels SPXL1, SPXL2, and SPXL3, but also an area where the components are provided may be referred to as the sub-pixel SPXL.

Referring to FIG. 2, the sub-pixel SPXL may include a light emitting unit EMU (or a light emitting unit) that generates light of a luminance corresponding to a data signal. In addition, the sub-pixel SPXL may further include a pixel circuit PXC for driving the light emitting unit EMU.

For example, the light emitting unit EMU may include a first connection electrode ELT1 connected to a first driving power (the first power source) VDD through the pixel circuit PXC and a first power line PL1, a fifth connection electrode ELT5 connected to a second driving power (the second power source) VSS through a second power line PL2, and a plurality of light emitting elements LD connected between the first and fifth connection electrodes ELT1 and ELT5. The first driving power VDD and the second driving power VSS may have different potentials so that the light emitting elements LD may emit light. For example, the first driving power VDD may be set as relatively high-potential power, and the second driving power VSS may be set as relatively low-potential power.

In one or more embodiments, the light emitting unit EMU may include at least one series stage. Each series stage may include a pair of electrodes (for example, two electrodes) and at least one light emitting element LD connected in a forward direction between the pair of electrodes. Here, the number of series stages configuring (e.g., forming) the light emitting unit EMU and the number of light emitting elements LD configuring (e.g., forming) each series stage are not particularly limited. For example, the number of light emitting elements LD configuring (e.g., forming) each series stage may be the same as or different from each other, and the number of light emitting elements LD is not particularly limited.

For example, the light emitting unit EMU may include a first series stage including at least one first light emitting element LD1, a second series stage including at least one second light emitting element LD2, a third series stage including at least one third light emitting elements LD3, and a fourth series stage including at least one fourth light emitting element LD4.

The first series stage may include the first connection electrode ELT1 and a second connection electrode ELT2 and at least one first light emitting element LD1 connected between the first and second connection electrodes ELT1 and ELT2. Each first light emitting element LD1 may be connected in the forward direction between the first and second connection electrodes ELT1 and ELT2. For example, a first end EP1 of the first light emitting element LD1 may be connected to the first connection electrode ELT1, and a second end EP2 of the first light emitting element LD1 may be connected to the second connection electrode ELT2.

The second series stage may include the second connection electrode ELT2 and a third connection electrode ELT3 and at least one second light emitting element LD2 connected between the second and third connection electrodes ELT2 and ELT3. Each second light emitting element LD2 may be connected in the forward direction between the second and third connection electrodes ELT2 and ELT3. For example, a first end EP1 of the second light emitting element LD2 may be connected to the second connection electrode ELT2, and a second end EP2 of the second light emitting element LD2 may be connected to the third connection electrode ELT3.

The third series stage may include the third connection electrode ELT3 and a fourth connection electrode ELT4 and at least one third light emitting element LD3 connected between the third and fourth connection electrodes ELT3 and ELT4. Each third light emitting element LD3 may be connected in the forward direction between the third and fourth connection electrodes ELT3 and ELT4. For example, a first end EP1 of the third light emitting element LD3 may be connected to the third connection electrode ELT3, and a second end EP2 of the third light emitting element LD3 may be connected to the fourth connection electrode ELT4.

The fourth series stage may include the fourth connection electrode ELT4 and the fifth connection electrode ELT5 and at least one fourth light emitting element LD4 connected between the fourth and fifth connection electrodes ELT4 and ELT5. Each fourth light emitting element LD4 may be connected in the forward direction between the fourth and fifth connection electrodes ELT4 and ELT5. For example, a first end EP1 of the fourth light emitting element LD4 may be connected to the fourth connection electrode ELT4, and a second end EP2 of the fourth light emitting element LD4 may be connected to the fifth connection electrode ELT5.

A first electrode of the light emitting unit EMU, for example, the first connection electrode ELT1, may be an anode electrode of the light emitting unit EMU. A last electrode of the light emitting unit EMU, for example, the fifth connection electrode ELT5, may be a cathode electrode of the light emitting unit EMU.

In a case where the light emitting elements LD are connected in a series/parallel structure, power efficiency may be improved compared to a case where the same number of light emitting elements LD are connected only in parallel. In addition, in the sub-pixel SPXL in which the light emitting elements LD are connected in the series/parallel structure, even though a short defect occurs in a partial series stage, because a certain luminance may be expressed (achieved) through the light emitting elements LD of the remaining stages, the possibility of having a dark spot defect in the sub-pixel SPXL may be reduced. However, the disclosure is not necessarily limited thereto, and the light emitting unit EMU may be configured (e.g., formed) by connecting the light emitting elements LD only in series, or the light emitting unit EMU may be configured (e.g., formed) by connecting the light emitting elements LD only in parallel.

Each of the light emitting elements LD may include a first end (for example, a p-type or kind end) connected to the first driving power VDD via at least one electrode (for example, the first connection electrode ELT1), the pixel circuit PXC, and/or the first power line PL1, and a second end (for example, an n-type or kind end) connected to the second driving power VSS via at least one other electrode (for example, the fifth connection electrode ELT5), the second power line PL2, and/or the like. For example, the light emitting elements LD may be connected in the forward direction between the first driving power VDD and the second driving power VSS. The light emitting elements LD connected in the forward direction may configure (e.g., form) effective light sources of the light emitting unit EMU.

When a driving current is supplied through the corresponding pixel circuit PXC, the light emitting elements LD may emit light with a luminance corresponding to the driving current. For example, during each frame period, the pixel circuit PXC may supply a driving current corresponding to a grayscale value to be expressed in a corresponding frame to the light emitting unit EMU. Accordingly, while the light emitting elements LD emit light with the luminance corresponding to the driving current, the light emitting unit EMU may express the luminance corresponding to the driving current.

The light emitting elements LD of the light emitting unit EMU may emit light with the luminance corresponding to the driving current supplied through the corresponding pixel circuit PXC. For example, the pixel circuit PXC may supply a driving current corresponding to a grayscale value of corresponding frame data to the light emitting unit EMU during each frame period. The driving current supplied to the light emitting unit EMU may be divided and flow to each of the light emitting elements LD. Accordingly, each of the light emitting elements LD may emit light with a luminance corresponding to the current flowing through the light emitting element LD, and thus the light emitting unit EMU may emit light of the luminance corresponding to the driving current.

The pixel circuit PXC may be connected to a scan line Si and a data line Dj of the corresponding sub-pixel SPXL. For example, when the sub-pixel SPXL is arranged in an i-th row and a j-th column of the display area DA, the pixel circuit PXC of the sub-pixel SPXL may be connected to the i-th scan line Si and the j-th data line Dj. In addition, the pixel circuit PXC may be connected to an i-th control line CLi and a j-th sensing line SENj of the display area DA.

The pixel circuit PXC may include first to third transistors T1, T2, and T3 and a storage capacitor Cst.

The first transistor T1 may be a driving transistor for controlling the driving current applied to the light emitting unit EMU, and may be connected between the first driving power VDD and the light emitting unit EMU. For example, a first terminal of the first transistor T1 may be connected (or coupled) to the first driving power VDD through the first power line PL1, a second terminal of the first transistor T1 may be connected to a second node N2, and a gate electrode of the first transistor T1 may be connected to a first node N1. The first transistor T1 may control an amount of the driving current applied from the first driving power VDD to the light emitting unit EMU through the second node N2, according to a voltage applied to the first node N1. In one or more embodiments, the first terminal of the first transistor T1 may be a drain electrode, and the second terminal of the first transistor T1 may be a source electrode, but the disclosure is not necessarily limited thereto. According to one or more embodiments, the first terminal may be a source electrode and the second terminal may be a drain electrode.

The second transistor T2 may be a switching transistor that selects the sub-pixel SPXL in response to a scan signal and activates the sub-pixel SPXL, and may be connected between the data line Dj and the first node N1. A first terminal of the second transistor T2 may be connected to the data line Dj, a second terminal of the second transistor T2 may be connected to the first node N1, and a gate electrode of the second transistor T2 may be connected to the scan line Si. The first terminal and the second terminal of the second transistor T2 may be different terminals. For example, when the first terminal is a drain electrode, the second terminal may be a source electrode.

The second transistor T2 may be turned on when a scan signal of a gate-on voltage (for example, a relatively high level voltage) is supplied from the scan line Si, to electrically connect the data line Dj and the first node N1. The first node N1 may be a point where the second terminal of the second transistor T2 and the gate electrode of the first transistor T1 are connected, and the second transistor T2 may transmit a data voltage to the gate electrode of the first transistor T1.

The third transistor T3 may connect the first transistor T1 to the sensing line SENj to obtain a sensing signal through the sensing line SENj, and detect a characteristic of the sub-pixel SPXL including a threshold voltage and/or the like of the first transistor T1 utilizing the sensing signal. Information on the characteristic of the sub-pixel SPXL may be utilized to convert image data so that a characteristic deviation between the sub-pixels SPXL may be compensated.

A first terminal of the third transistor T3 may be connected to initialization power. The third transistor T3 may be an initialization transistor capable of initializing the second node N2, and may transmit a voltage of the initialization power to the second node N2 when turned on because a sensing control signal is supplied from the control line CLi. Accordingly, a second storage electrode (or an upper electrode) of the storage capacitor Cst connected to the second node N2 may be initialized. A second terminal of the third transistor T3 may be connected to the second terminal of the first transistor T1, the first terminal of the third transistor T3 may be connected to the sensing line SENj, and a gate electrode of the third transistor T3 may be connected to the control line CLi.

A first storage electrode of the storage capacitor Cst may be connected to the first node N1, and the second storage electrode of the storage capacitor Cst may be connected to the second node N2. The storage capacitor Cst charges a data voltage corresponding to the data signal supplied to the first node N1 during one frame period. Accordingly, the storage capacitor Cst may store a voltage corresponding to a voltage difference between a voltage of the gate electrode of the first transistor T1 and a voltage of the second node N2.

In FIG. 2, an embodiment in which all of the first to third transistors T1, T2, and T3 are n-type or kind transistors is disclosed, but the disclosure is not necessarily limited thereto. For example, at least one of the above-described first to third transistors T1, T2, and T3 may be changed to a p-type or kind transistor. In addition, in FIG. 2, an embodiment in which the light emitting unit EMU is connected between the pixel circuit PXC and the second driving power VSS is disclosed, but disclosure is not necessarily limited thereto and the light emitting unit EMU may be connected between the first driving power VDD and the pixel circuit PXC.

The structure of the pixel circuit PXC may be variously suitably changed. For example, the pixel circuit PXC may further include at least one transistor element such as a transistor element for initializing the first node N1 and/or a transistor element for controlling an emission time of the light emitting elements LD, and/or other circuit elements such as a boosting capacitor for boosting the voltage of the first node N1.

FIG. 3 is a perspective view schematically illustrating a light emitting element in accordance with one or more embodiments. FIG. 4 is a cross-sectional view schematically illustrating a light emitting element in accordance with one or more embodiments. FIGS. 3 and 4 show a column shape light emitting element LD, but a type or kind and/or a shape of the light emitting element LD are/is not necessarily limited thereto.

Referring to FIGS. 3 and 4, the light emitting element LD may include a first semiconductor layer 11, an active layer 12, a second semiconductor layer 13, and/or an electrode layer 14.

The light emitting element LD may be formed in a column shape extending along one direction. The light emitting element LD may have a first end EP1 and a second end EP2. One of the first and second semiconductor layers 11 and 13 may be arranged at the first end EP1 of the light emitting element LD. The other of the first and second semiconductor layers 11 and 13 may be arranged at the second end EP2 of the light emitting element LD. For example, the first semiconductor layer 11 may be arranged at the first end EP1 of the light emitting element LD, and the second semiconductor layer 13 may be arranged at the second end EP2 of the light emitting element LD.

According to one or more embodiments, the light emitting element LD may be a light emitting element manufactured in a column shape through an etching method and/or the like. In the present specification, the column shape includes a rod-like shape or a bar-like shape, of which an aspect ratio is greater than 1, such as a circular column or a polygonal column, and the shape of the cross-section thereof is not limited.

The light emitting element LD may have a size as small as in a nanometer scale and/or in a micrometer scale. For example, each light emitting element LD may have a (e.g., cross-section) diameter D (or major axis or width) and/or a length L of (from)nanometer to micrometer range. However, a size of the light emitting element LD is not necessarily limited thereto, and the size of the light emitting element LD may be variously suitably changed according to a design condition of one or more suitable devices utilizing the light emitting element LD as a light source, for example, a display device and/or the like.

The first semiconductor layer 11 may be a semiconductor layer of a first conductivity type or kind. For example, the first semiconductor layer 11 may include a p-type or kind semiconductor layer. For example, the first semiconductor layer 11 may include at least one semiconductor material of InAlGaN, GaN, AlGaN, InGaN, or AlN, and may include a p-type or kind semiconductor layer doped with a first conductivity type or kind dopant such as Mg. However, a material configuring (e.g., forming) the first semiconductor layer 11 is not necessarily limited thereto, and one or more suitable other materials may configure (e.g., be utilized to form) the first semiconductor layer 11.

The active layer 12 may be arranged between the first semiconductor layer 11 and the second semiconductor layer 13. The active layer 12 may include any one of a single well structure, a multi well structure, a single quantum well structure, a multi quantum well (MQW) structure, a quantum dot structure, or a quantum wire structure, but the present disclosure is not necessarily limited thereto. The active layer 12 may include GaN, InGaN, InAlGaN, AlGaN, or AlN, and one or more suitable other materials may configure (e.g., be utilized to form) the active layer 12.

When a voltage equal to or greater than a threshold voltage is applied to both ends (e.g., opposite ends) of the light emitting element LD, an electron-hole pair is combined in the active layer 12 and thus the light emitting element LD emits light. By controlling emission of the light emitting element LD utilizing such a principle, the light emitting element LD may be utilized as a light source of one or more suitable light emitting devices including a pixel of a display device.

The second semiconductor layer 13 may be arranged on the active layer 12 and may include a semiconductor layer of a type or kind different from that of the first semiconductor layer 11. The second semiconductor layer 13 may include an n-type or kind semiconductor layer. For example, the second semiconductor layer 13 may include any one semiconductor material selected from among InAlGaN, GaN, AlGaN, InGaN, and AlN, and may include an n-type or kind semiconductor layer doped with a second conductivity type or kind dopant such as Si, Ge, and/or Sn. However, a material configuring (e.g., forming) the second semiconductor layer 13 is not necessarily limited thereto, and one or more other suitable materials may configure (e.g., be utilized to form) the second semiconductor layer 13.

The electrode layer 14 may be arranged on the first end EP1 and/or the second end EP2 of the light emitting element LD. FIG. 4 illustrates a case in which the electrode layer 14 is formed on the first semiconductor layer 11, but the disclosure is not necessarily limited thereto. For example, a separate contact electrode may be further arranged on the second semiconductor layer 13.

The electrode layer 14 may include a transparent metal or a transparent metal oxide. For example, the electrode layer 14 may include at least one of indium tin oxide (ITO), indium zinc oxide (IZO), or zinc tin oxide (ZTO), but the present disclosure is not necessarily limited thereto. As described above, when the electrode layer 14 is formed of the transparent metal or the transparent metal oxide, light generated in the active layer 12 of the light emitting element LD may pass through the electrode layer 14 and may be emitted to an outside of the light emitting element LD.

An insulating layer INF may be provided on a surface of the light emitting element LD. The insulating layer INF may be directly arranged on a surface of the first semiconductor layer 11, the active layer 12, the second semiconductor layer 13, and/or the electrode layer 14. The insulating layer INF may expose the first and second ends EP1 and EP2 of the light emitting element LD having different polarities. According to one or more embodiments, the insulating layer INF may expose a side portion of the electrode layer 14 and/or the second semiconductor layer 13 adjacent to the first and second ends EP1 and EP2 of the light emitting element LD.

The insulating layer INF may prevent or reduce an electrical short (e.g., short circuit) that may occur when the active layer 12 comes into contact with a conductive material except for the first and second semiconductor layers 11 and 13. The insulating layer INF may minimize or reduce a surface defect of the light emitting elements LD, thereby improving lifespan and emission efficiency of the light emitting elements LD.

The insulating layer INF may include at least one of silicon oxide (SiOx), silicon nitride (SiNx), silicon oxynitride (SiOxNy), aluminum nitride (AlNx), aluminum oxide (AIOx), zirconium oxide (ZrOx), hafnium oxide (HfOx), or titanium oxide (TiOx). For example, the insulating layer INF may be configured (e.g., formed) as double layers, and each layer configuring (e.g., forming) the double layers may include different materials. For example, the insulating layer INF may be configured (e.g., formed) as double layers configured (e.g., formed) of aluminum oxide (AIOx) and silicon oxide (SiOx), but the present disclosure is not necessarily limited thereto. According to one or more embodiments, the insulating layer INF may not be provided.

A light emitting device including the light emitting element LD described above may be utilized in one or more suitable types (kinds) of devices that require a light source, including a display device. For example, the light emitting elements LD may be arranged in each pixel of a display panel, and the light emitting elements LD may be utilized as a light source of each pixel. However, an application field of the light emitting element LD is not limited to the above-described example. For example, the light emitting element LD may also be utilized in other types (kinds) of devices that require a light source, such as a lighting device.

FIG. 5 is a plan view schematically illustrating a sub-pixel in accordance with one or more embodiments.

Referring to FIG. 5, each sub-pixel SPXL may include the light emitting elements LD (refer to FIG. 2), connection electrodes ELT, and/or sub-electrodes SLT. For example, FIG. 5 may be one of the first to third sub-pixels SPXL1, SPXL2, and SPXL3 configuring (e.g., forming) the pixel PXL of FIG. 1, and the first to third sub-pixels SPXL1, SPXL2, and SPXL3 may have structures substantially equal or similar to each other. In addition, FIG. 5 shows an embodiment in which each sub-pixel SPXL includes the light emitting elements LD arranged in four serial stages as shown in FIG. 2, but the number of series stages of each sub-pixel SPXL may be variously suitably changed according to one or more embodiments.

Hereinafter, when one or more light emitting elements selected from among the first to fourth light emitting elements LD1, LD2, LD3, and LD4 are arbitrarily referred to, or when two or more types (kinds) of light emitting elements are comprehensively (e.g., collectively) referred to, the one or more light emitting elements or the two or more types (kinds) of light emitting elements are referred to as the “light emitting element LD” or the “light emitting elements LD.” In addition, when at least one electrode selected from among electrodes including the first to fifth connection electrodes ELT1, ELT2, ELT3, ELT4, and ELT5 is referred to, the at least one electrode is referred to as a “connection electrode ELT” or “connection electrodes ELT”. In addition, when at least one electrode selected from among electrodes including first to fourth sub-electrodes SLT1, SLT2, SLT3, and SLT4 is referred to, the at least one electrode is referred to as a “sub-electrode SLT” or “sub-electrodes SLT”.

The light emitting elements LD may be electrically connected between a pair of connection electrodes ELT in each emission area.

The first light emitting element LD1 may be electrically connected between the first and second connection electrodes ELT1 and ELT2. For example, the first end EP1 of the first light emitting element LD1 may be electrically connected to the first connection electrode ELT1, and the second end EP2 of the first light emitting element LD1 may be electrically connected to the second connection electrode ELT2.

The second light emitting element LD2 may be electrically connected between the second and third connection electrodes ELT2 and ELT3. For example, the first end EP1 of the second light emitting element LD2 may be electrically connected to the second connection electrode ELT2, and the second end EP2 of the second light emitting element LD2 may be electrically connected to the third connection electrode ELT3.

The third light emitting element LD3 may be electrically connected between the third and fourth connection electrodes ELT3 and ELT4. For example, the first end EP1 of the third light emitting element LD3 may be electrically connected to the third connection electrode ELT3, and the second end EP2 of the third light emitting element LD3 may be electrically connected to the fourth connection electrode ELT4.

The fourth light emitting element LD4 may be electrically connected between the fourth and fifth connection electrodes ELT4 and ELT5. For example, the first end EP1 of the fourth light emitting element LD4 may be electrically connected to the fourth connection electrode ELT4, and the second end EP2 of the fourth light emitting element LD4 may be electrically connected to the fifth connection electrode ELT5.

For example, the first light emitting element LD1 may be positioned in an upper left area of the emission area, and the second light emitting element LD2 may be positioned in a lower left area of the emission area. The third light emitting element LD3 may be positioned in a lower right area of the emission area, and the fourth light emitting element LD4 may be positioned in an upper right area of the emission area. However, an arrangement, a connection structure, and/or the like of the first to fourth light emitting elements LD1, LD2, LD3, and LD4 may be variously suitably changed according to a structure of the light emitting unit EMU, the number of series stages, and/or the like.

Each of the connection electrodes ELT may be provided in the emission area and may be arranged to overlap at least one light emitting element LD. For example, each connection electrode ELT may be formed on the light emitting elements LD to overlap the light emitting elements LD, and may be electrically connected to the light emitting elements LD.

The first connection electrode ELT1 may be arranged on the first ends EP1 of the first light emitting elements LD1, and may be electrically connected to the first ends EP1 of the first light emitting elements LD1.

The second connection electrode ELT2 may be arranged on the second ends EP2 of the first light emitting elements LD1, and may be electrically connected to the second ends EP2 of the first light emitting elements LD1. In addition, the second connection electrode ELT2 may be arranged on the first ends EP1 of the second light emitting elements LD2, and may be electrically connected to the first ends EP1 of the second light emitting elements LD2. For example, the second connection electrode ELT2 may electrically connect the second ends EP2 of the first light emitting elements LD1 and the first ends EP1 of the second light emitting elements LD2 in the emission area. To this end (e.g., in this embodiment), the second connection electrode ELT2 may have a curved shape. For example, the second connection electrode ELT2 may have a bent or curved structure at a boundary between an area where the at least one first light emitting element LD1 is arranged and an area where the at least one second light emitting element LD2 is arranged.

The third connection electrode ELT3 may be arranged on the second ends EP2 of the second light emitting elements LD2, and may be electrically connected to the second ends EP2 of the second light emitting elements LD2. In addition, the third connection electrode ELT3 may be arranged on the first ends EP1 of the third light emitting elements LD3, and may be electrically connected to the first ends EP1 of the third light emitting elements LD3. For example, the third connection electrode ELT3 may electrically connect the second ends EP2 of the second light emitting elements LD2 and the first ends EP1 of the third light emitting elements LD3 in the emission area. To this end (e.g., in this embodiment), the third connection electrode ELT3 may have a curved shape. For example, the third connection electrode ELT3 may have a bent or curved structure at a boundary between an area where the at least one second light emitting element LD2 is arranged and an area where the at least one third light emitting element LD3 is arranged.

The fourth connection electrode ELT4 may be arranged on the second ends EP2 of the third light emitting elements LD3, and may be electrically connected to the second ends EP2 of the third light emitting elements LD3. In addition, the fourth connection electrode ELT4 may be arranged on the first ends EP1 of the fourth light emitting elements LD4, and may be electrically connected to the first ends EP1 of the fourth light emitting elements LD4. For example, the fourth connection electrode ELT4 may electrically connect the second ends EP2 of the third light emitting elements LD3 and the first ends EP1 of the fourth light emitting elements LD4 in the emission area. To this end (e.g., in this embodiment), the fourth connection electrode ELT4 may have a curved shape. For example, the fourth connection electrode ELT4 may have a bent or curved structure at a boundary between an area where at least one third light emitting element LD3 is arranged and an area where at least one fourth light emitting element LD4 is arranged.

The fifth connection electrode ELT5 may be arranged on the second ends EP2 of the fourth light emitting elements LD4, and may be electrically connected to the second ends EP2 of the fourth light emitting elements LD4.

In the method described above, the light emitting elements LD may be connected in a desired or suitable form utilizing the connection electrodes ELT. For example, the first light emitting elements LD1, the second light emitting elements LD2, the third light emitting elements LD3, and the fourth light emitting elements LD4 may be sequentially connected in series utilizing the connection electrodes ELT.

The sub-electrodes SLT may be electrically connected to the connection electrodes ELT, respectively. For example, the first sub-electrode SLT1 may be electrically connected to the second connection electrode ELT2, the second sub-electrode SLT2 may be electrically connected to the third connection electrode ELT3, the third sub-electrode SLT3 may be electrically connected to the fourth connection electrode ELT4, and the fourth sub-electrode SLT4 may be electrically connected to the fifth connection electrode ELT5.

In some embodiments, the first sub-electrode SLT1 may be provided integrally with the second connection electrode ELT2, the second sub-electrode SLT2 may be provided integrally with the third connection electrode ELT3, the third sub-electrode SLT3 may be provided integrally with the fourth connection electrode ELT4, and the fourth sub-electrode SLT4 may be provided integrally with the fifth connection electrode ELT5, but the disclosure is not necessarily limited thereto.

In some embodiments, the sub-electrodes SLT may be spaced and/or apart (e.g., spaced apart or separated) from the connection electrodes ELT, and the sub-electrodes SLT and the connection electrodes ELT may be electrically connected through connection portions CN1 and CN2, respectively. For example, one end of the sub-electrodes SLT may be electrically connected to the connection electrodes ELT through the first connection portion CN1. Another end of the sub-electrodes SLT may be electrically connected to the connection electrodes ELT through the second connection portion CN2. For example, the first connection portion CN1 and/or the second connection portion CN2 may be provided integrally with the sub-electrodes SLT and/or the connection electrodes ELT and may be arranged on the same layer as the sub-electrodes SLT and/or the connection electrodes ELT, but the disclosure is not necessarily limited thereto.

The sub-electrodes SLT may extend along the second direction DR2 and may be spaced and/or apart (e.g., spaced apart or separated) from the connection electrodes ELT in the first direction DR1. The first connection portion CN1 and/or the second connection portion CN2 may extend along the first direction DR1 between the sub-electrodes SLT and the connection electrodes ELT. As described above, when the sub-electrodes SLT electrically connected to the connection electrodes ELT are formed, a dark spot defect of the sub-pixel SPXL may be reduced or improved.

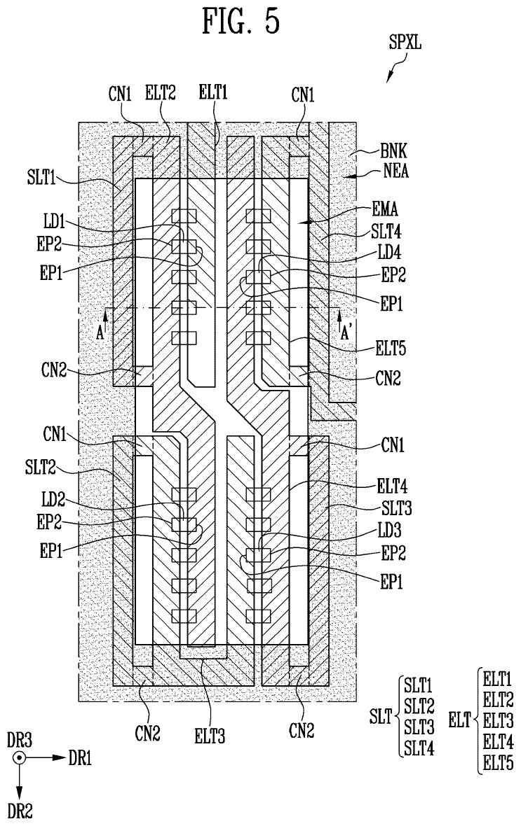

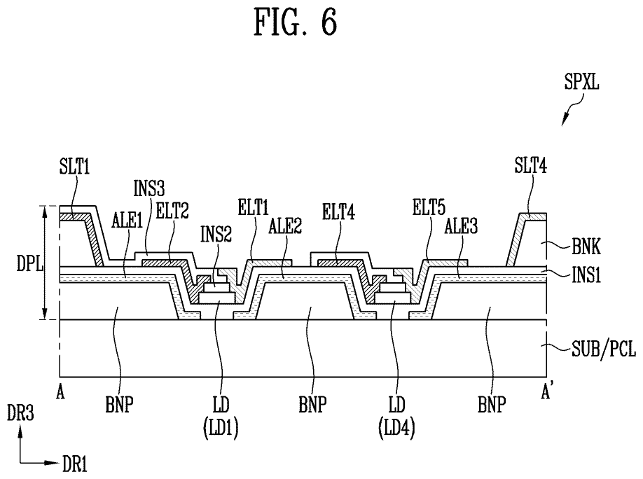

FIG. 6 is a cross-sectional view taken along the line A-A′ of FIG. 5.

Referring to FIG. 6, the sub-pixel SPXL according to one or more embodiments may include a light emitting element layer DPL arranged on the substrate SUB and a pixel circuit layer PCL. The light emitting element layer DPL may include bank patterns BNP, first to third electrodes ALE1, ALE2, ALE3, the light emitting elements LD, the connection electrodes ELT (refer to FIG. 5), and/or the sub-electrodes SLT (refer to FIG. 5).

The bank patterns BNP may be arranged on the substrate SUB. The bank patterns BNP may have one or more suitable shapes according to one or more embodiments. In one or more embodiments, the bank patterns BNP may have a shape protruding in a third direction DR3 on the substrate SUB. In some embodiments, the bank patterns BNP may be formed to have an inclined surface inclined at a set or predetermined angle with respect to the substrate SUB. However, the disclosure is not necessarily limited thereto, and the bank patterns BNP may have a sidewall of a curved surface, a step shape, and/or the like. For example, the bank patterns BNP may have a cross-section of a semicircular or semielliptical shape, and/or the like.

Electrodes and insulating layers arranged on the bank patterns BNP may have a shape corresponding to the bank patterns BNP. For example, the first to third electrodes ALE1, ALE2, and ALE3 arranged on the bank patterns BNP may include an inclined surface or a curved surface having a shape corresponding to the shape of the bank patterns BNP. Accordingly, the bank patterns BNP may function as a reflective member improving light output efficiency by guiding light emitted from the light emitting elements LD in a front surface direction of the pixel PXL, that is, in the third direction DR3, together with the electrodes provided thereon.

The bank patterns BNP may include at least one organic material and/or at least one inorganic material. For example, the bank patterns BNP may include an organic material such as acrylic resin, epoxy resin, phenolic resin, polyamide resin, polyimide resin, polyester resin, polyester resin, polyphenylenesulfide resin, and/or benzocyclobutene (BCB). However, the disclosure is not necessarily limited thereto, and the bank patterns BNP may include one or more suitable types (kinds) of inorganic materials including silicon oxide (SiOx), silicon nitride (SiNx), silicon oxynitride (SiOxNy), aluminum nitride (AlNx), aluminum oxide (AIOx), zirconium oxide (ZrOx), hafnium oxide (HfOx), and/or titanium oxide (TiOx).

The first to third electrodes ALE1, ALE2, and ALE3 may be arranged on the bank patterns BNP. The first to third electrodes ALE1, ALE2, and ALE3 may be arranged to be spaced and/or apart (e.g., spaced apart or separated) from each other in the sub-pixel SPXL. The first to third electrodes ALE1, ALE2, and ALE3 may be arranged on the same layer. For example, the first to third electrodes ALE1, ALE2, and ALE3 may be formed concurrently (e.g., simultaneously) in substantially the same process, but the disclosure is not necessarily limited thereto.

The first to third electrodes ALE1, ALE2, and ALE3 may receive an alignment signal in an alignment (e.g., act or task) step of the light emitting elements LD. Accordingly, an electric field may be formed between the first to third electrodes ALE1, ALE2, and ALE3, and the light emitting elements LD provided to each of the sub-pixels SPXL may be aligned between the first to third electrodes ALE1, ALE2, and ALE3. For example, the first light emitting elements LD1 may be aligned between the first and second electrodes ALE1 and ALE2, and the fourth light emitting elements LD4 may be aligned between the second and third electrodes ALE2 and ALE3. In some embodiments, the second light emitting elements LD2 shown in FIG. 5 may be aligned between the first and second electrodes ALE1 and ALE2, and the third light emitting elements LD3 may be aligned between the second and third electrodes ALE2 and ALE3.

Each of the first to third electrodes ALE1, ALE2, and ALE3 may include at least one conductive material. For example, each of the first to third electrodes ALE1, ALE2, and ALE3 may include at least one conductive material selected from among: metal materials (e.g., metals), such as silver (Ag), magnesium (Mg), aluminum (AI), platinum (Pt), palladium (Pd), gold (Au), nickel (Ni), neodymium (Nd), iridium (Ir), chromium (Cr), titanium (Ti), molybdenum (Mo), and/or copper Cu; alloys including the same; conductive oxides, such as indium tin oxide (ITO), indium zinc oxide (IZO), indium tin zinc oxide (ITZO), aluminum zinc oxide (AZO), gallium zinc oxide (GZO), zinc tin oxide (ZTO), and/or gallium tin oxide (GTO); and conductive polymers, such as PEDOT, but the present disclosure is not necessarily limited thereto.

A first insulating layer INS1 may be arranged on the first to third electrodes ALE1, ALE2, and ALE3. The first insulating layer INS1 may be configured (e.g., formed) as a single layer or multiple layers, and may include one or more suitable types (kinds) of inorganic materials including silicon oxide (SiOx), silicon nitride (SiNx), silicon oxynitride (SiOxNy), aluminum nitride (AlNx), aluminum oxide (AIOx), zirconium oxide (ZrOx), hafnium oxide (HfOx), and/or titanium oxide (TiOx).

A bank BNK may be arranged on the first insulating layer INS1. The bank BNK may form a dam structure that partitions an emission area to which the light emitting elements LD are to be supplied in a step (e.g., act or task) of supplying the light emitting elements LD to each of the sub-pixels SPXL. For example, a desired or suitable type or kind and/or amount of light emitting element ink may be supplied to an area partitioned by the bank BNK.

The bank BNK may include an organic material such as acrylic resin, epoxy resin, phenolic resin, polyamide resin, polyimide resin, polyester resin, polyester resin, polyphenylenesulfide resin, and/or benzocyclobutene (BCB). However, the disclosure is not necessarily limited thereto, and the bank BNK may include one or more suitable types (kinds) of inorganic materials including silicon oxide (SiOx), silicon nitride (SiNx), silicon oxynitride (SiOxNy), aluminum nitride (AlNx), aluminum oxide (AIOx), zirconium oxide (ZrOx), hafnium oxide (HfOx), and/or titanium oxide (TiOx).

According to one or more embodiments, the bank BNK may include at least one light blocking and/or reflective material. Accordingly, light leakage between adjacent sub-pixels SPXL may be prevented or reduced. For example, the bank BNK may include at least one black matrix material, color filter material, and/or the like. For example, the bank BNK may be formed as a black and opaque pattern that may block or reduce transmission of light. In one or more embodiments, a reflective layer and/or the like may be formed on a surface (for example, a sidewall) of the bank BNK to increase light efficiency of each sub-pixel SPXL.

The light emitting elements LD may be arranged on the first insulating layer INS1. The light emitting elements LD may be arranged between the first to third electrodes ALE1, ALE2, and ALE3 on the first insulating layer INS1. The light emitting elements LD may be prepared in a form dispersed in a light emitting element ink and supplied to each of the sub-pixels SPXL through an inkjet printing method and/or the like. For example, the light emitting elements LD may be dispersed in a volatile solvent and provided to each of the sub-pixels SPXL. Subsequently, when an alignment signal is supplied to the first to third electrodes ALE1, ALE2, and ALE3, an electric field may be formed between the first to third electrodes ALE1, ALE2, and ALE3, and thus the light emitting elements LD may be aligned between the first to third electrodes ALE1, ALE2, and ALE3. After the light emitting elements LD are aligned, the light emitting elements LD may be stably arranged between the first to third electrodes ALE1, ALE2, and ALE3 by evaporating the solvent or removing the solvent in another suitable method.

A second insulating layer INS2 may be arranged on the light emitting elements LD. For example, the second insulating layer INS2 may be partially provided on the light emitting elements LD and may expose the first and second ends EP1 and EP2 of the light emitting elements LD. When the second insulating layer INS2 is formed on the light emitting elements LD after alignment of the light emitting elements LD is completed, the light emitting elements LD may be prevented or reduced from being separated from an aligned position.

The second insulating layer INS2 may be configured (e.g., formed) as a single layer or multiple layers, and may include one or more suitable types (kinds) of inorganic materials including silicon oxide (SiOx), silicon nitride (SiNx), silicon oxynitride (SiOxNy), aluminum nitride (AlNx), aluminum oxide (AIOx), zirconium oxide (ZrOx), hafnium oxide (HfOx), and/or titanium oxide (TiOx).

The connection electrodes ELT (refer to FIG. 5) may be arranged on the first and second ends EP1 and EP2 of the light emitting elements LD exposed by the second insulating layer INS2.

The first connection electrode ELT1 may be directly arranged on the first end EP1 of the first light emitting elements LD1 to contact the first end EP1 of the first light emitting elements LD1.

The second connection electrode ELT2 may be directly arranged on the second end EP2 of the first light emitting elements LD1 to contact the second end EP2 of the first light emitting elements LD1. In addition, the second connection electrode ELT2 may be directly arranged on the first end EP1 of the second light emitting elements LD2 to contact the first end EP1 of the second light emitting elements LD2. For example, the second connection electrode ELT2 may electrically connect the second end EP2 of the first light emitting elements LD1 and the first end EP1 of the second light emitting elements LD2.

The fourth connection electrode ELT4 may be directly arranged on the second end EP2 of the third light emitting elements LD3 to contact the second end EP2 of the third light emitting elements LD3. In addition, the fourth connection electrode ELT4 may be directly arranged on the first end EP1 of the fourth light emitting elements LD4 to contact the first end EP1 of the fourth light emitting elements LD4. For example, the fourth connection electrode ELT4 may electrically connect the second end EP2 of the third light emitting elements LD3 and the first end EP1 of the fourth light emitting elements LD4.

The fifth connection electrode ELT5 may be directly arranged on the second end EP2 of the fourth light emitting elements LD4 to contact the second end EP2 of the fourth light emitting elements LD4.

In some embodiments, the third connection electrode ELT3 shown in FIG. 5 may be directly arranged on the second end EP2 of the second light emitting elements LD2 to contact the second end EP2 of the second light emitting elements LD2. In addition, the third connection electrode ELT3 may be directly arranged on the first end EP1 of the third light emitting elements LD3 to contact the first end EP1 of the third light emitting elements LD3. For example, the third connection electrode ELT3 may electrically connect the second end EP2 of the second light emitting elements LD2 and the first end EP1 of the third light emitting elements LD3.

The connection electrodes ELT may be configured (e.g., formed) of a plurality of conductive layers. For example, the first connection electrode ELT1, the third connection electrode ELT3, and/or the fifth connection electrode ELT5 may be formed of the same conductive layer. For example, the first connection electrode ELT1, the third connection electrode ELT3, and/or the fifth connection electrode ELT5 may be formed concurrently (e.g., simultaneously) in substantially the same process. In addition, the second connection electrode ELT2 and/or the fourth connection electrode ELT4 may be formed of the same conductive layer. For example, the second connection electrode ELT2 and/or the fourth connection electrode ELT4 may be formed concurrently (e.g., simultaneously) in substantially the same process. For example, a third insulating layer INS3 may be arranged on the second connection electrode ELT2 and/or the fourth connection electrode ELT4, the first connection electrode ELT1, the third connection electrode ELT3, and/or the fifth connection electrode ELT5 may be arranged on the third insulating layer INS3. The third insulating layer INS3 may be configured (e.g., formed) as a single layer or multiple layers, and may include one or more suitable types (kinds) of inorganic materials including silicon oxide (SiOx), silicon nitride (SiNx), silicon oxynitride (SiOxNy), aluminum nitride (AlNx), aluminum oxide (AIOx), zirconium oxide (ZrOx), hafnium oxide (HfOx), and/or titanium oxide (TiOx).

When the third insulating layer INS3 is arranged between the connection electrodes ELT formed of the plurality of conductive layers, because the connection electrodes ELT may be stably separated by the third insulating layer INS3, electrical stability between the first and second ends EP1 and EP2 of the light emitting elements LD may be secured.

Each of the connection electrodes ELT may be formed of one or more suitable transparent conductive materials. For example, the connection electrodes ELT may include at least one selected from among transparent conductive materials including indium tin oxide (ITO), indium zinc oxide (IZO), indium tin zinc oxide (ITZO), aluminum zinc oxide (AZO), gallium zinc oxide (GZO), zinc tin oxide (ZTO), and/or gallium tin oxide (GTO), and may be implemented to be substantially transparent or translucent to satisfy a set or predetermined light transmittance. Accordingly, light emitted from the first and second ends EP1 and EP2 of the light emitting elements LD may pass through the connection electrodes ELT and may be emitted to an outside.

The sub-electrodes SLT (refer to FIG. 5) may be arranged on the same layer as the connection electrodes ELT, respectively. For example, the sub-electrodes SLT and the connection electrodes ELT electrically connected to each other, and the connection portions CN1 and CN2 (refer to FIG. 5) connecting the sub-electrodes SLT and the connection electrodes ELT may be integrally provided and may be arranged on the same layer.

For example, the first sub-electrode SLT1 may be arranged on the same layer as the second connection electrode ELT2. For example, the first sub-electrode SLT1 may be formed concurrently (e.g., simultaneously) with the second connection electrode ELT2 in substantially the same process, but the present disclosure is not necessarily limited thereto. In addition, the second sub-electrode SLT2 may be arranged on the same layer as the third connection electrode ELT3. For example, the second sub-electrode SLT2 may be formed concurrently (e.g., simultaneously) with the third connection electrode ELT3 in substantially the same process, but the present disclosure is not necessarily limited thereto. In addition, the third sub-electrode SLT3 may be arranged on the same layer as the fourth connection electrode ELT4. For example, the third sub-electrode SLT3 may be formed concurrently (e.g., simultaneously) with the fourth connection electrode ELT4 in substantially the same process, but the present disclosure is not necessarily limited thereto. In addition, the fourth sub-electrode SLT4 may be arranged on the same layer as the fifth connection electrode ELT5. For example, the fourth sub-electrode SLT4 may be formed concurrently (e.g., simultaneously) with the fifth connection electrode ELT5 in substantially the same process, but the present disclosure is not necessarily limited thereto.

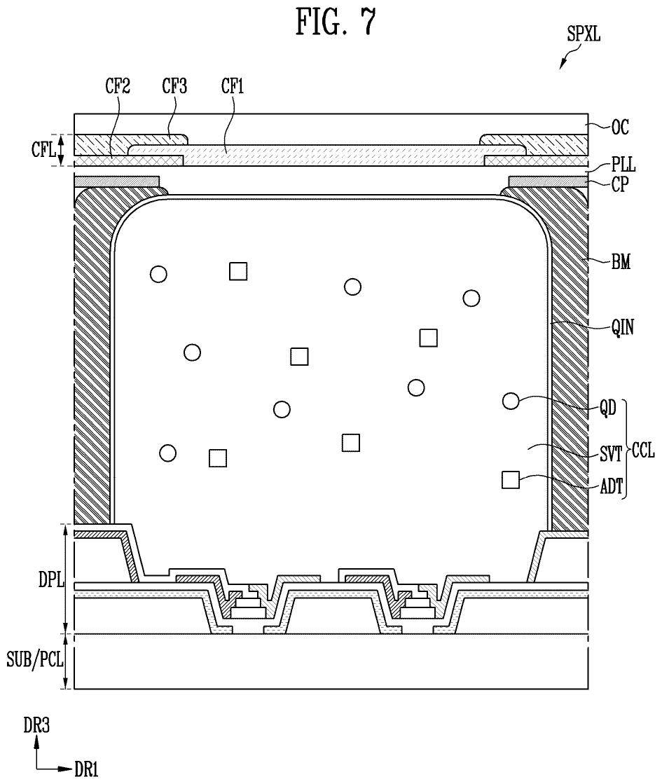

FIG. 7 is a cross-sectional view schematically illustrating a sub-pixel in accordance with one or more embodiments. FIG. 7 shows a color conversion layer CCL, a black matrix pattern BM, a color filter layer CFL, an overcoat layer OC, and/or the like provided on the light emitting element layer DPL of the sub-pixel SPXL shown in FIG. 6.

Referring to FIG. 7, the color conversion layer CCL may be arranged on the light emitting element layer DPL. For example, the color conversion layer CCL may be adjacent to the light emitting element layer DPL. When the color conversion layer CCL is adjacent to the light emitting element layer DPL, a distance between the color conversion layer CCL and the light emitting elements LD (refer to FIG. 6) may become decreased, and thus efficiency of the display device DD (refer to FIG. 1) may be improved.

The color conversion layer CCL may include a quantum dot ink composition. In one or more embodiments, the quantum dot ink composition may include a solvent SVT, a quantum dot (e.g., a plurality of quantum dots) QD, and an additive ADT.

The solvent SVT may uniformly (e.g., substantially uniformly) disperse the quantum dot QD. For example, the solvent SVT may be an organic solvent. For example, the solvent SVT may include 1-octadecene (ODE), trioctylamine (TOA), trioctylphosphine (TOP), or any combination thereof.

The quantum dot QD may include a Group II-VI semiconductor compound, a Group III-V semiconductor compound, a Group III-VI semiconductor compound, a Group I-III-VI semiconductor compound, a Group IV-VI semiconductor compound, a Group IV element or compound, or any combination thereof.

For example, the Group II-VI semiconductor compound may include a binary compound such as CdS, CdSe, CdTe, ZnS, ZnSe, ZnTe, ZnO, HgS, HgSe, HgTe, MgSe, and/or MgS, a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, and/or MgZnS, a quaternary compound such as CdZnSeS, CdZnSeTe, CdZnSTe, CdHgSeS, CdHgSeTe, CdHgSTe, HgZnSeS, HgZnSeTe, and/or HgZnSTe, or any combination thereof.

For example, the Group III-V semiconductor compound may include a binary compound such as GaN, GaP, GaAs, GaSb, AlN, AIP, AIAs, AISb, InN, InP, InAs, and/or InSb, a ternary compound such as GaNP, GaNAs, GaNSb, GaPAs, GaPSb, AlNP, AlNAs, AlNSb, AIPAs, AIPSb, InGaP, InNP, InAIP, InNAs, InNSb, InPAs, and/or InPSb, a ternary compound such as GaAINP, GaAINAs, GaAINSb, GaAIPAs, GaAIPSb, GaInNP, GaInNAs, GalnNSb, GaInPAs, GalnPSb, InAINP, InAINAs, InAINSb, InAIPAs, and/or InAIPSb, or any combination thereof. According to one or more embodiments, the Group III-V semiconductor compound may further include a Group II element. For example, the Group III-V semiconductor compound may include InZnP, InGaZnP, InAIZnP, or any combination thereof.

For example, the Group III-VI semiconductor compound may include a binary compound such as GaS, GaSe, Ga2Se3, GaTe, InS, InSe, In₂S₃, In₂Se₃, and/or InTe, a ternary compound such as InGaS₃ and/or InGaSes, or any combination thereof.

For example, the Group I-III-VI semiconductor compound may include a ternary compound such as AgInS, AgInS₂, CuInS, CuInS₂, CuGaO₂, AgGaO₂, and/or AgAlO₂, or any combination thereof.

For example, the Group IV-VI semiconductor compound may include a binary compound such as SnS, SnSe, SnTe, PbS, PbSe, and/or PbTe, a ternary compound such as SnSeS, SnSeTe, SnSTe, PbSeS, PbSeTe, PbSTe, SnPbS, SnPbSe, and/or SnPbTe, a quaternary compound such as SnPbSSe, SnPbSeTe, and/or SnPbSTe, or any combination thereof.

For example, the Group IV element or compound may include a single element compound such as Si and/or Ge, a binary compound such as SiC and/or SiGe, or any combination thereof.

Each element included in the multi-element compound such as the binary compound, the ternary compound, and/or the quaternary compound may exist in a particle at a substantially uniform concentration or a non-uniform concentration.

The quantum dot QD may be configured (e.g., formed) of at least one type or kind corresponding to a color emitted from the sub-pixel SPXL. For example, when the sub-pixel SPXL is a red pixel for emitting red light, the quantum dot QD may be a red quantum dot that converts blue light emitted from the light emitting elements LD into red light. In addition, when the sub-pixel SPXL is a green pixel for emitting green light, the quantum dot QD may be a green quantum dot that converts blue light emitted from the light emitting elements LD into green light.

For example, when the sub-pixel SPXL is a blue pixel for emitting blue light, the quantum dot QD may be a blue quantum dot that converts green or red light emitted from the light emitting elements LD into blue light.

According to one or more embodiments, the color conversion layer CCL may not include (e.g., may exclude) the quantum dot QD. For example, when the sub-pixel SPXL is a blue pixel emitting blue light and the light emitting elements LD emit blue light, the color conversion layer CCL may include at least one type or kind of light scattering particle.

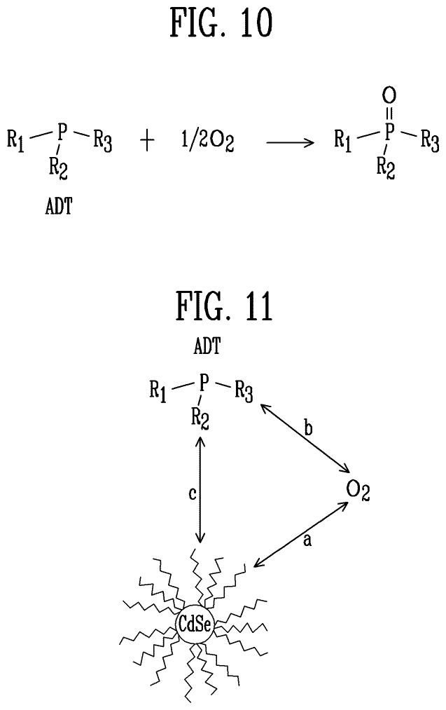

The additive ADT is for preventing or reducing deterioration of the quantum dot QD by removing oxygen. The additive ADT is described in more detail later with reference to FIG. 10.

According to one or more embodiments, the quantum dot ink composition may further include an initiator. For example, the initiator may include a thermal polymerization initiator and/or a photopolymerization initiator, but a type or kind of the initiator is not particularly limited.

According to one or more embodiments, the quantum dot ink composition may further include a dispersant and a viscosity control agent for improving discharge and applicability, and a type or kind of the dispersant and the viscosity control agent is not particularly limited. In addition, the quantum dot ink composition may further include a scattering agent for improving an optical property, and a type or kind of the scattering agent is not particularly limited.

According to one or more embodiments, the quantum dot ink composition may further include a monomer. For example, the monomer may be a diacrylate-based compound. In some embodiments, the diacrylate-based compound may include an alkyldiol diacrylate compound. In some embodiments, the alkyldiol diacrylate compound may include a hexanediol diacrylate compound.

An optical insulating layer QIN may be arranged on a surface of the color conversion layer CCL. The optical insulating layer QIN may be arranged to be around (e.g., surround) the color conversion layer CCL and may at least partially overlap the light emitting element layer DPL.

The optical insulating layer QIN may be an inorganic insulating layer. For example, the optical insulating layer QIN may include one or more suitable types (kinds) of inorganic materials, including silicon nitride (SiNx), silicon oxide (SiOx, silicon oxynitride (SiOxNy), and/or aluminum oxide (AIOx).

The black matrix pattern BM may be arranged on both sides (e.g., opposite sides) of the color conversion layer CCL. For example, the black matrix pattern BM may be positioned to directly contact a side surface of the optical insulating layer QIN.

The black matrix pattern BM may include at least one black matrix material (for example, at least one suitable light blocking material) among one or more suitable types (kinds) of black matrix materials, a color filter material of a specific color, and/or the like.

A conductive pattern CP may be arranged on the black matrix pattern BM. For example, the conductive pattern CP may be positioned to at least partially overlap the black matrix pattern BM.

The conductive pattern CP may include a transparent electrode material. For example, the conductive pattern CP may include a transparent conductive oxide such as indium tin oxide (ITO), indium zinc oxide (IZO), zinc oxide (ZnO), indium gallium zinc oxide (IGZO), and/or indium tin zinc oxide (ITZO), but the present disclosure is not limited thereto.

The conductive pattern CP may include a conductive polymer material. For example, the conductive pattern CP may include a conductive polymer such as polyacetylene, polypyrrole, polythiophene, poly(3,4-ethylenedioxythiophene (PEDOT), and/or polyaniline, but the present disclosure is not limited thereto.

A planarization layer PLL may be arranged on the color conversion layer CCL, the optical insulating layer QIN, and the conductive pattern CP. The planarization layer PLL may be configured (e.g., formed) as a single layer or multiple layers including at least one organic layer. For example, the planarization layer PLL may include a low-refractive organic layer, thereby securing light efficiency of the sub-pixel SPXL.

The color filter layer CFL may be arranged on the planarization layer PLL. The color filter layer CFL may include first to third color filters CF1, CF2, and CF3 that match a color emitted from the sub-pixel SPXL. For example, when the sub-pixel SPXL is a red pixel that emits red light, the first color filter CF1 may be a red color filter. In addition, when a sub-pixel adjacent to the sub-pixel SPXL, which is the red pixel, is a green pixel that emits green light, the second color filter CF2 may be a green color filter. In addition, when another sub-pixel adjacent to the sub-pixel SPXL, which is the red pixel, is a blue pixel, the third color filter CF3 may be a blue color filter.

The first to third color filters CF1, CF2, and CF3 positioned to overlap the black matrix pattern BM in the color filter layer CFL may overlap each other and may have a light blocking function similar to the black matrix pattern BM.

The overcoat layer OC may be arranged on the color filter layer CFL to cover the color filter layer CFL. The overcoat layer OC may be a planarization layer for alleviating a step (or bump) of a lower structure, and may include one or more suitable types (kinds) of organic materials including polyimide, benzocyclobutene series resin, and acrylate.

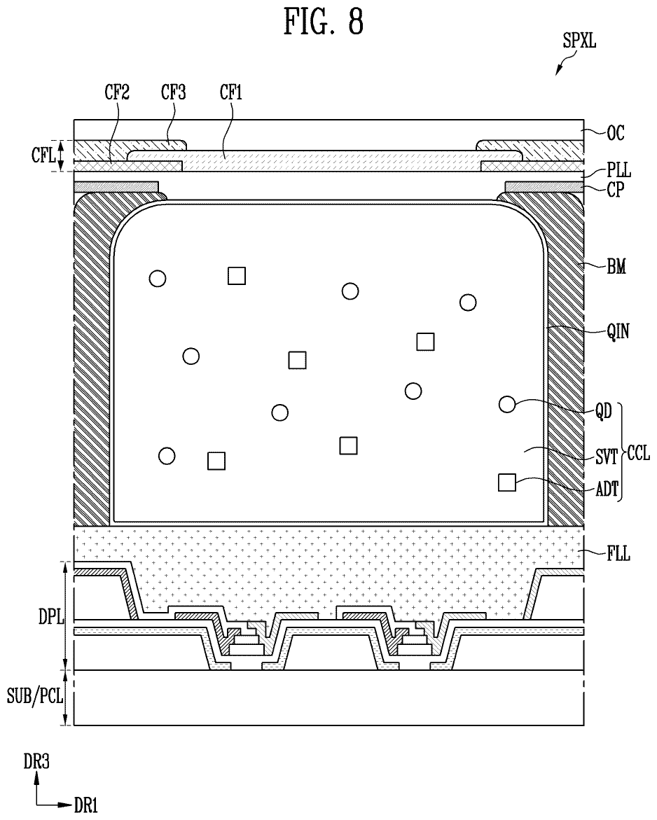

FIG. 8 is a cross-sectional view schematically illustrating a sub-pixel in accordance with one or more embodiments. Regarding FIG. 8, a description of a content (e.g., amount) overlapping that of FIG. 7 is omitted (not be provided) or simplified.

Referring to FIG. 8, the color conversion layer CCL may be arranged to be spaced and/or apart (e.g., spaced apart or separated) from the light emitting element layer DPL. Compared to FIG. 7, a distance between the color conversion layer CCL and the light emitting elements LD (refer to FIG. 6) may become increased. For example, a filler FLL may be arranged between the light emitting element layer DPL and the color conversion layer CCL. The filler FLL may secure stability of the display device DD by preventing or reducing damage to the display device DD (see FIG. 1) due to impact and/or the like. The filler FLL may be formed of a material having both (e.g., simultaneously) elasticity and adhesiveness.

The optical insulating layer QIN may be arranged to entirely around (e.g., surround, e.g., entirely surround or encapsulate) the color conversion layer CCL. For example, the optical insulating layer QIN may be arranged between the color conversion layer CCL and the filler FLL.

According to one or more embodiments, the optical insulating layer QIN around (e.g., surrounding) a lower portion of the color conversion layer CCL may not be provided. In this case, the color conversion layer CCL may be adjacent to the filler FLL.

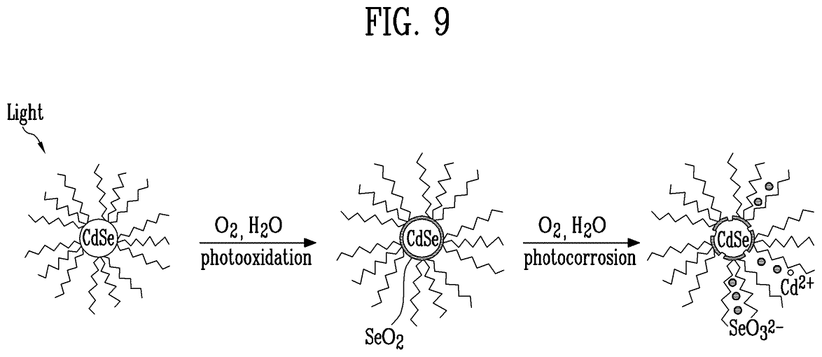

FIG. 9 is a diagram schematically illustrating a deterioration phenomenon of the quantum dot. FIG. 9 shows that the quantum dot QD shown in FIG. 7 or 8 is CdSe as an example.

Referring to FIG. 9, when light is applied to CdSe in a state in which oxygen exists, a surface of CdSe may be passivated (or oxidized) to SeO₂ due to photooxidation represented by formula 1.

CdSe+O₂->Cd²⁺+SeO₂ Formula 1

In addition, when light is applied to CdSe in a state in which moisture exists, the surface of CdSe may be partially passivated due to photoadsorption.

When the surface of CdSe is passivated through photoadsorption and/or photooxidation, a surface defect of CdSe may be removed, and photoluminescence quantum yield PLQY of CdSe may be increased. However, when light is continuously applied to CdSe in a state in which oxygen and moisture exist, CdSe may be deteriorated due to photocorrosion represented by formula 2, and the PLQY of CdSe may be decreased (e.g., rapidly decreased).

CdSe+H₂O+O₂->Cd²⁺+2H⁺+SeO₃²⁻ Formula 2

In order to prevent or reduce deterioration of the quantum dot QD (refer to FIG. 7 or FIG. 8) due to photocorrosion, at least one of oxygen, moisture, or light is desired or required to be removed. However, because light is an essential element in the display device DD (see FIG. 1) and thus the light may not be removed, thus the other elements, such as oxygen and/or moisture should be removed or are required to be removed.

FIGS. 10 and 11 are diagrams schematically illustrating a function of the additive. FIG. 11 shows that the quantum dot QD shown in FIG. 7 or 8 is CdSe as an example.

Referring to FIG. 10, the additive ADT may include a phosphine compound. The phosphine compound may react with oxygen to form a phosphine oxide. For example, the phosphine compound may remove oxygen. In particular, because the phosphine compound has relatively higher reactivity with oxygen at room temperature, deterioration of the quantum dot QD (refer to FIG. 7 or FIG. 8) due to photocorrosion may be effectively prevented or reduced.

In one or more embodiments, the phosphine compound may be 20% (wt %) or less by weight based on a total weight of (100% or wt % of) the quantum dot ink composition. When a content (e.g., amount) of the phosphine compound exceeds the above-described range, the phosphine compound may react competitively with a ligand coupled to a surface of the quantum dot QD, the ligand may be detached, and thus a characteristic of the quantum dot QD may be reduced or deteriorated. When the phosphine compound includes two types (kinds) of phosphine compounds, each may be 10% (wt %) or less by weight based on the total weight of the quantum dot ink composition.

In one or more embodiments, a boiling point of the phosphine compound may be 250 to 450° C. When the boiling point of the phosphine compound is less than the above-described range, the phosphine compound may be vaporized before a process is progressed, and thus removing oxygen may be difficult. In addition, when the boiling point of the phosphine compound exceeds the above-described range, the phosphine compound may remain in a solid form after the process is progressed, uniformity may be reduced, and thus a characteristics of the color conversion layer CCL (refer to FIG. 7 or 8) may be reduced or deteriorated.

In one or more embodiments, the phosphine compound may be one type or kind of phosphine compound or two or more types (kinds) of phosphine compounds. For example, the phosphine compound may include any of (e.g., any one selected from among) compounds represented by the formulas 3 to 13, or any combination of (e.g., selected from among) the compounds represented by the formulas 3 to 13.

In one or more embodiments, the phosphine compound may be the compound represented by formula 3.

P(R₁)(R₂)(R₃) Formula 3

In formula 3, each of R₁, R₂, and R₃ may independently include one or more suitable types (kinds) of functional groups including at least one of a hydrogen atom, a deuterium atom, a substituted or unsubstituted alkyl group, a substituted or unsubstituted aryl group, or a substituted or unsubstituted amine group.

In one or more embodiments, the phosphine compound may be the compound represented by formula 4.

PR₃ Formula 4

In formula 4, R may be CₙH₂ₙ₊₁ (n is an integer selected from 2 to 8). For example, the phosphine compound may include one type or kind of trialkylphosphine compound.

In one or more embodiments, the phosphine compound may include a first compound and a second compound represented by formula 4 above. For example, the first compound may be a compound in which R in Formula 4 is represented by CₚH₂ₚ₊₁ (p is an integer selected from 2 to 8). For example, the second compound may be a compound in which R in formula 4 is represented by C_{q}H_{2q+1} (q is an integer selected from 2 to 8 excluding p (e.g., p and q are different)). For example, the phosphine compound may include two types (kinds) of trialkylphosphine compound of different lengths.

Table 1 illustrates PLQY of a comparative example, Example 1, Example 2, and Example 3. The comparative example represents a case where the quantum dot ink composition does not include the phosphine compound. Example 1 and Example 2 each represent a case where the quantum dot ink composition includes one type or kind of trialkylphosphine compound. The quantum dot ink composition of Example 1 includes trioctylphosphine (TOP), and the quantum dot ink composition of Example 2 includes tributylphosphine (TBP). Example 3 represent a case where the quantum dot ink composition includes two types (kinds) of trialkylphosphine compounds. The quantum dot ink composition of Example 3 includes trioctylphosphine (TOP) and tributylphosphine (TBP).

TABLE 1

| No | PLQY (%) |
|---|---|
| Comparative example | 51 |
| Embodiment 1 | 83 |
| Embodiment 2 | 84 |
| Embodiment 3 | 86 |

Referring to table 1, it may be seen that the PLQY of Example 1 and Example 2 including the phosphine compound is increased significantly compared to the comparative example that does not include the phosphine compound. Without being bound by any particular theory, it is believed that this is because oxygen is removed by the phosphine compound and thus photocorrosion of the quantum dot QD (refer to FIG. 7 or FIG. 8) is suppressed or reduced. In addition, it may be seen that the PLQY of Example 3 including two types (kinds) of trialkylphosphine compounds is increased compared to Example 1 and Example 2 including one type or kind of trialkylphosphine compound. Without being bound by any particular theory, it is believed that this is because trioctylphosphine (TOP), which is not vaporized due to a relatively high boiling point, removes oxygen that is not removed due to vaporization of tributylphosphine (TBP), which has a relatively low boiling point, and thus photocorrosion of the quantum dot QD is further suppressed or reduced.

In one or more embodiments, the phosphine compound may include two or more phosphine groups. For example, the phosphine compound may be any of the compounds represented by the formulas 5 to 9. Formula 5, formula 6, and formula 7 each represent compounds including two phosphine groups. Formula 7 represents a compound including a hetero atom between two phosphine groups. Formula 8 represents a compound including three phosphine groups, and formula 9 represents a compound including four phosphine groups.

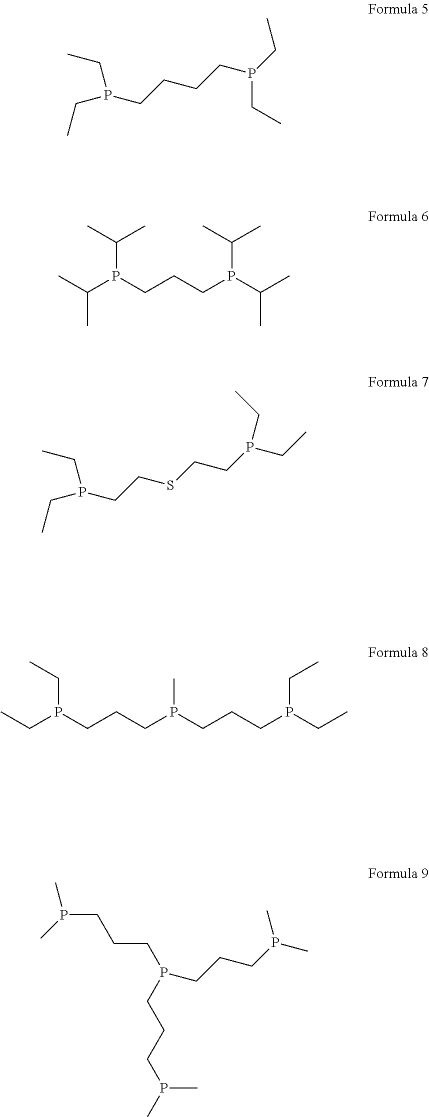

In one or more embodiments, the phosphine compound may include a ligand including a phosphine group. For example, the phosphine compound may be any of (e.g., any one selected from among) the compounds represented by formula 10 and formula 11.

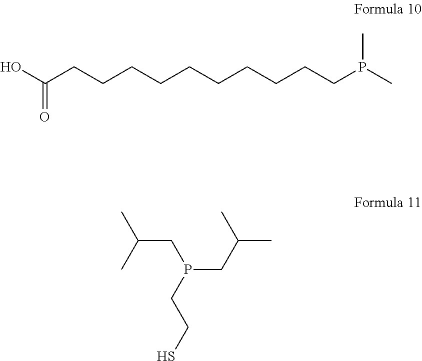

In one or more embodiments, the phosphine compound may include a monomer including a phosphine group. For example, the phosphine compound may be any of (e.g., any one selected from among) the compounds represented by formula 12 and formula 13.

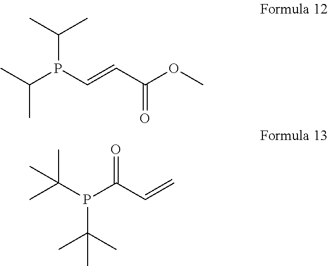

Referring to FIG. 11, adsorption force a between CdSe and oxygen may be greater than adsorption force b between the phosphine compound, which is the additive ADT, and oxygen. However, because the phosphine compound adsorbs oxygen competitively with CdSe, the phosphine compound may reduce an amount of oxygen adsorbed on CdSe. In addition, the adsorption force b between the phosphine compound and oxygen may be greater than adsorption force c between the phosphine compound and CdSe. Therefore, the phosphine compound may effectively remove oxygen without significantly affecting CdSe.

According to one or more embodiments of the present disclosure, emission efficiency of a quantum dot may be improved by removing oxygen by adding a phosphine compound to a quantum dot ink composition.

However, aspects and features of the present disclosure are not limited to those described above, and one or more suitable other aspects and features would be understood by one of ordinary skill in the art within the spirit and scope of the present disclosure.

In the context of the present application and unless otherwise defined, the terms “use,” “using,” and “used” may be considered synonymous with the terms “utilize,” “utilizing,” and “utilized,” respectively.

The use of “may” when describing embodiments of the inventive concept refers to “one or more embodiments of the inventive concept.”

As used herein, the term “about,” and similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A battery management system (BMS) device, and/or any other relevant devices or components according to embodiments of the present invention described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

The embodiments described in more detail above are provided to explain the present disclosure, but these embodiments are not intended to limit the scope of the present disclosure. It should be understood by those skilled in the art that one or more suitable changes, substitutions, and alternations may be made therein without departing from the scope of the disclosure as defined by the following claims and equivalents thereof.

The scope of the present disclosure is not limited by the detailed descriptions of the present specification and should be defined by the accompanying claims and their equivalents. Furthermore, all changes or modifications of the present disclosure derived from the claims, and equivalents thereof, should be construed as being included in the scope of the present disclosure. The embodiments may be combined to form additional embodiments.

What is claimed is:

1. A quantum dot ink composition comprising:
a quantum dot;
a solvent; and
a phosphine compound.

2. The quantum dot ink composition according to claim 1, wherein the phosphine compound is 20% or less by weight based on a total weight of the quantum dot ink composition.

3. The quantum dot ink composition according to claim 1, wherein the phosphine compound comprises one kind of phosphine compound.

4. The quantum dot ink composition according to claim 1, wherein the phosphine compound comprises two or more kinds of phosphine compounds.

5. The quantum dot ink composition according to claim 1, wherein the phosphine compound is a compound represented by PR₃, where R is CₙH₂ₙ₊₁ and n is an integer selected from 2 to 8.

6. The quantum dot ink composition according to claim 1, wherein the phosphine compound comprises a first compound represented by P(R₁)₃, where R₁ is CₚH₂ₚ₊₁ and p is an integer selected from among 2 to 8, and a second compound represented by P(R₂)₃, where R₂ is C_{q}H_{2q+1} and q is an integer selected from 2 to 8, and p and q are different.

7. The quantum dot ink composition according to claim 6, wherein each of the first compound and the second compound is 10% or less by weight based on a total weight of the quantum dot ink composition.

8. The quantum dot ink composition according to claim 1, further comprising:
a monomer, a dispersant, a scattering agent, and an initiator.

9. The quantum dot ink composition according to claim 1, wherein the phosphine compound is to react with oxygen to suppress photocorrosion of the quantum dot.

10. The quantum dot ink composition according to claim 1, wherein the quantum dot comprises a Group II-VI semiconductor compound, a Group III-V semiconductor compound, a Group III-VI semiconductor compound, a Group I-III-VI semiconductor compound, a Group IV-VI semiconductor compound, a Group IV element or compound, or any combination thereof.

11. A display device comprising:
a substrate;
a pixel circuit layer on the substrate;
a light emitting element layer on the pixel circuit layer; and
a color conversion layer comprising a quantum dot ink composition,
wherein the quantum dot ink composition comprises:
a quantum dot;
a solvent; and
a phosphine compound.

12. The display device according to claim 11, wherein the color conversion layer is adjacent to the light emitting element layer.

13. The display device according to claim 11, wherein the phosphine compound is 20% or less by weight based on a total weight of the quantum dot ink composition.

14. The display device according to claim 11, wherein the phosphine compound comprises one kind of phosphine compound.

15. The display device according to claim 11, wherein the phosphine compound comprises two or more kinds of phosphine compounds.

16. The display device according to claim 11, wherein the phosphine compound is a compound represented by PR₃, where R is CₙH₂ₙ₊₁ and n is an integer selected from among 2 to 8.

17. The display device according to claim 11, wherein the phosphine compound comprises a first compound represented by P(R₁)₃, where R₁ is CₚH₂ₚ₊₁ and p is an integer selected from 2 to 8, and a second compound represented by P(R₂)₃, where R₂ is C_{q}H_{2q+1} and q is an integer selected from 2 to 8, and p and q are different.

18. The display device according to claim 17, wherein each of the first compound and the second compound is 10% or less by weight based on a total weight of the quantum dot ink composition.

19. The display device according to claim 11, wherein the quantum dot ink composition further comprises a monomer, a dispersant, a scattering agent, and an initiator.

20. The display device according to claim 1, wherein the phosphine compound is to react with oxygen to suppress photocorrosion of the quantum dot.
